(19) United States
(12) Patent Application Publication
(10) Pub. No.: US 2025/0393288 A1
(43) Pub. Date: Dec. 25, 2025

(54) T-Gate FET Structure

(71) Applicant: pSemi Corporation, San Diego, CA (US)

(72) Inventors: Jagar Singh, Clifton Park, NY (US); Ronald Eugene Reedy, San Diego, CA (US)

(21) Appl. No.: 18/750,645

(22) Filed: Jun. 21, 2024

(51) Int. Cl. H01L 29/49; H01L 29/423

(52) U.S. Cl. CPC H10D 64/663; H10D 64/518; H10D 64/679

(57) ABSTRACT

Device structures and fabrication methods for MOSFETs having a novel multiple-conductive layer “T”-shaped gate (as viewed in cross-section). The novel “T-gate” significantly decreases the gate resistance R_{G} of a MOSFET device and thus increases the figure-of-merit f_{MAX} (the maximum device oscillation frequency, or the frequency at which the maximum power gain equals unity) and reduces the noise factor (NF) of the device. Fabrication of the novel MOSFET devices may be readily integrated into existing IC fabrication processes, and such MOSFETs may have gate lengths L_{g} scaled below the lithographic capabilities of the fabrication process. Some embodiments include conformal gate side-spacers. Some embodiments include non-conformal air-gapped gate side-spacers that result in reduced parasitic gate-to-source capacitance C_{GS} and gate-to-drain capacitance C_{GD}, with concomitant improved performance at high radio frequencies (RF). Embodiments of the novel MOSFET device enable RF circuits, such as low-noise amplifiers (LNAs), to exhibit a better noise figure parameter, NFmin.

### BACKGROUND

### (1) Technical Field

This invention relates to electronic integrated circuit (IC) devices, and more particularly to metal-oxide-semiconductor field-effect transistor (MOSFET) devices.

### (2) Background

Virtually all modern electronic products—including laptop computers, mobile telephones, and electric cars—utilize MOSFET-based integrated circuits (ICs). A number of architectural variations exist for MOSFETs. One type of MOSFET is an N-type FET (NFET), which has N+ doped source and drain regions abutting opposite sides of a channel region, which, for an enhancement-mode device, may be doped with P-type material. Another type of MOSFET is a P-type FET (PFET), which has P+ doped source and drain regions abutting opposite sides of a channel region, which, for an enhancement-mode device, may be doped with N-type material.

FIG. 1A is a stylized cross-sectional view of an SOI IC structure for a prior art NFET 100. The SOI structure includes a substrate 102, a buried-oxide (BOX) insulator layer 104, and an active layer 106 (note that the dimensions for the elements of the SOI IC structure are not to scale; some dimensions have been exaggerated for clarity or emphasis). The substrate 102 is typically a semiconductor material such as silicon (Si), but may be other materials such as glass or sapphire. The BOX layer 104 is a dielectric and is often SiO₂ formed as a “top” surface of the substrate 102; for some substrates (e.g., glass or sapphire, a BOX layer 104 optionally may be omitted. Some embodiments may include a trap-rich Si layer (not shown) between the BOX layer 104 substrate 102. A trap-rich Si layer mitigates parasitic surface conduction and improves device performance at high frequencies.

The active layer 106 may include some combination of implants and/or layers that include dopants, dielectrics, polysilicon, conductors, passivation, and other materials to form active and/or passive electronic components and/or mechanical structures. For example, the NFET 100 of FIG. 1A has an active layer 106 that includes an N+ source 108, a P-type body region or “P-well” 110 in which an electrically conductive channel can be formed, and an N+ drain 112, all bounded by an isolation structure 114, such as a shallow trench isolation (STI) structure.

Optional features within the active layer 106 include a halo region 116 and a lightly-doped drain (LDD) region 118 (“LDD” being somewhat of a misnomer, since an LDD region 118 is also on the source-side of the device for the illustrated embodiment). A halo implant mitigates punch-through while an LDD region mitigates avalanche breakdown. More specifically, the halo region 116 increases a sub-surface electric field to reduce so-called punch-through, or short channel, conduction between the source 108 and the drain 112, thus increasing the channel breakdown voltage. The LDD region 118 extends the source 108 underneath a gate structure 120 and modulates the threshold voltage V_{TH}, transconductance Gm, and leakage current of the device.

The gate structure 120 is formed in contact with a surface of the active layer 106, positioned with respect to the P-well 110 so as to be able to influence current flow through the P-well 110 between the source 108 and the drain 112. The gate structure 120 includes a conductive layer 122, such as N+ doped polysilicon, in contact with an insulating gate oxide (GOX) layer 124. In the illustrated example, the gate structure 120 is surrounded by insulating side-spacers 126.

A conductive source contact 130, a conductive gate contact 132, and a conductive drain contact 134, which may be self-aligned silicides (also known as “salicides”), are respectively formed in contact with the source 108, the conductive layer 122 of the gate structure 120, and the drain 112. The salicides may be, for example, nickel silicide (NiSi). Stylized electrical terminals S, G, and D are shown coupled to the corresponding source contact 130, gate contact 132, and drain contact 134.

The gate structure 120, the BOX layer 104, and the active layer 106 (which may include multiple FETs) may be collectively referred to as a “device region” or “substructure” for convenience (noting that other structures or regions may intrude into the substructure in particular IC designs). A superstructure (not shown) of various elements, regions, and structures may be fabricated on or above the substructure in order to implement particular functionality. The superstructure may include, for example, conductive interconnections from the illustrated NFET 100 to other components (including other FETs on the same IC die) and/or external contacts, passivation layers, and protective coatings.

FIG. 1B is a stylized cross-sectional view of a variant SOI IC structure for a prior art NFET 150. Similar in many aspects to the NFET 100 of FIG. 1A, the NFET 150 differs in that the conductive layer 122 (e.g., N+ doped polysilicon) is formed in a monolithic “T”-shape to increase the cross-sectional area of the conductive layer 122 and thus reduce the horizontal resistance R_{H} across the width of the gate (note that halo regions and LDD regions are omitted to reduce clutter).

PFET devices have a similar structure, but with opposite polarities for the dopants (e.g., with a P+ doped source, drain, and conductive layer). NFET and PFET devices may be combined on the same substrate to create complementary metal-oxide-semiconductor (CMOS) circuitry.

### SUMMARY

The present invention encompasses device structures and related fabrication methods for MOSFETs having a novel multiple-conductive layer “T”-shaped gate (as viewed in cross-section). The novel “T-gate” significantly decreases the gate resistance R_{G} of a MOSFET device and thus increases the figure-of-merit f_{MAX} (the maximum device oscillation frequency, or the frequency at which the maximum power gain equals unity) and reduces the noise factor (NF) of the device. Fabrication of the novel MOSFET devices may be readily integrated into existing IC fabrication processes, and such MOSFETs may have gate lengths L_{g} scaled below the lithographic capabilities of the fabrication process. Some embodiments include conformal gate side-spacers. Some embodiments include non-conformal air-gapped gate side-spacers that result in reduced parasitic gate-to-source capacitance C_{GS} and gate-to-drain capacitance C_{GD}, with concomitant improved performance at high radio frequencies (RF). Embodiments of the novel MOSFET device enable RF circuits, such as low-noise amplifiers (LNAs), to exhibit a better noise figure parameter, NFmin.

In one aspect, the present invention encompasses a multiple-conductive layer T-shaped gate for a MOSFET, including: a gate oxide layer in contact with an active layer of the FET; a first conductive layer in contact with the gate oxide layer; a second conductive layer in contact with the first conductive layer; and a conductive gate contact in contact with the second conductive layer; wherein at least the first conductive layer has a shorter length than the conductive gate contact and a higher etch rate than the second conductive layer.

In another aspect, the present invention encompasses a MOSFET having an active layer and including: a source region formed within the active layer of the MOSFET; a drain region formed within the active layer of the MOSFET; a body region within the active layer of the MOSFET between the source region and the drain region; and a multiple-conductive layer T-shaped gate structure overlying the body region, the gate structure having a source region side and a drain region side and positioned to influence current flow through the body region, the multiple-conductive layer T-shaped gate structure including: a gate oxide layer in contact with an active layer of the FET; a poly-SiGe layer in contact with the gate oxide layer; a polysilicon layer in contact with the poly-SiGe layer; and a conductive gate contact in contact with the polysilicon layer; wherein at least the poly-SiGe layer has a shorter length than the conductive gate contact.

The T-shaped gate structure may be formed by etching sides of a poly-SiGe layer more than sides of a polysilicon layer so as to form a multiple-conductive layer T-shape; etching may be by re-oxidation or by using a liquid or gaseous etchant.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized cross-sectional view of an SOI IC structure for a prior art NFET.

FIG. 1B is a stylized cross-sectional view of a variant SOI IC structure for a prior art NFET.

FIG. 2 is a stylized cross-sectional view of an SOI IC structure for a first example T-gate NFET in accordance with the present invention.

FIG. 3 is a stylized cross-sectional view of an SOI IC structure for a second example T-gate NFET in accordance with the present invention.

FIGS. 4A-4H are cross-sectional stylized views of example fabrication stages for one method of fabricating the T-gate NFET structure shown in FIG. 2.

FIGS. 5A-5C are cross-sectional stylized views of example fabrication stages for one method of fabricating the T-gate NFET structure shown in FIG. 3.

FIG. 6 is a process flowchart showing another representation of an example fabrication process for the T-gate NFET of FIG. 2.

FIG. 7 is a process flowchart showing another representation of an example fabrication process for the T-gate NFET of FIG. 3.

FIG. 8 is a simplified schematic diagram of an LNA circuit.

FIG. 9 is a top plan view of a substrate that may be, for example, a printed circuit board or chip module substrate (e.g., a thin-film tile).

FIG. 10 illustrates a prior art wireless communication environment comprising different wireless communication systems, and which may include one or more mobile wireless devices.

FIG. 11 is a block diagram of a transceiver that might be used in a wireless device, such as a cellular telephone, and which may beneficially incorporate an embodiment of the present invention for improved performance.

Like reference numbers and designations in the various drawings indicate like elements unless the context requires otherwise.

### DETAILED DESCRIPTION

The present invention encompasses device structures and related fabrication methods for MOSFETs having a novel “T”-shaped gate (as viewed in cross-section). The novel “T-gate” significantly decreases the gate resistance R_{G} of a MOSFET device and thus increases the figure-of-merit f_{MAX} (the maximum device oscillation frequency, or the frequency at which the maximum power gain equals unity). Fabrication of the novel MOSFET devices may be readily integrated into existing IC fabrication processes, and such MOSFETs may have gate lengths L_{g} scaled below the lithographic capabilities of the fabrication process.

Some embodiments include conformal gate side-spacers. Some embodiments include non-conformal air-gapped gate side-spacers that result in reduced parasitic gate-to-source capacitance C_{GS} and gate-to-drain capacitance C_{GD}, with concomitant improved performance at high radio frequencies (RF).

A shorter gate length improves the Gm (transconductance) and hence the Noise Figure of the device. Gate length also sets the f_{T}, and typically the f_{MAX}, of the device, which in turn improves the Gm of the device at any given frequency. Accordingly, embodiments of the novel MOSFET device enable RF circuits, such as low-noise amplifiers (LNAs), to exhibit a better noise figure parameter, NFmin.

In RF circuits (particularly LNAs), an important parameter of performance for a MOSFET device is f_{MAX}, which can be computed in terms of the gate resistance R_{G} (shown in the equation below as R_{g}) and parasitic capacitance C_{GD} of the device, the transition frequency f_{T} of the device (the unity current gain cut-off frequency), and the output resistance rₒ, as follows:

$${f}_{MAX} = \frac{1}{2} \frac{{f}_{T}}{\sqrt{2 π \times {f}_{T} \times {C}_{gel} {R}_{g} + \frac{{R}_{g}}{{r}_{o}}}}$$

From this above equation, it follows that f_{MAX} is undesirably reduced at higher values of R_{G}. A component of the gate resistance R_{G} is the parallel resistance of the conductive gate contact 132 (e.g., silicide) and the gate conductive layer 122 (commonly monolithic doped polysilicon in a conventional MOSFET device), both of which are proportional to gate length.

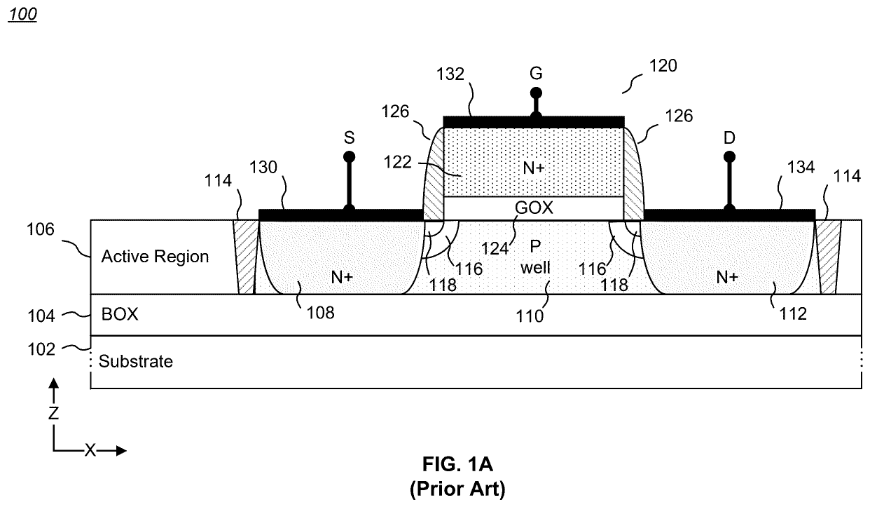

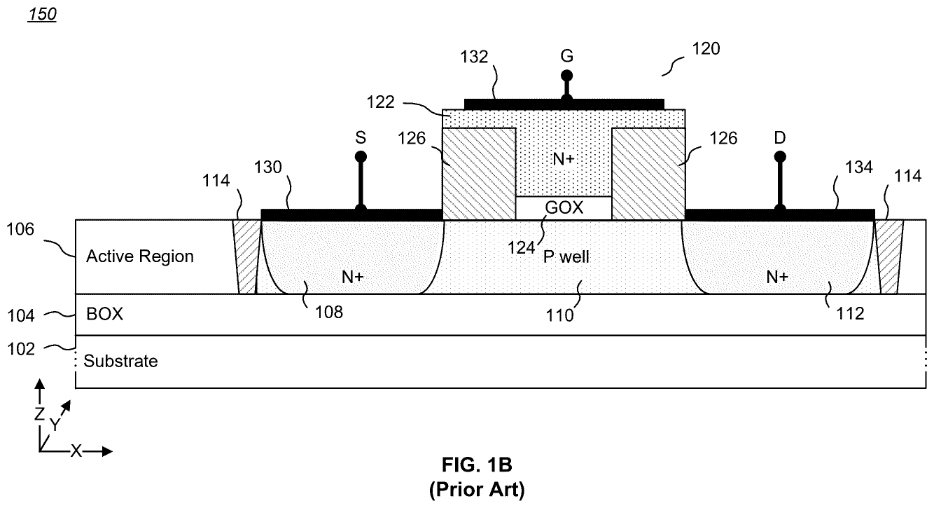

One aspect of the present invention is the realization that small changes in IC structure and/or material can result in significant improvements in performance. It was realized by the inventors that minimization of the R_{H} resistance is particularly important for very wide MOSFET devices. A simplistic approach taken in prior art T-gate MOSFETs such as is shown in FIG. 1B increases the length (i.e., in the X-dimension) of a portion of the monolithic gate conductive layer 122 relative to the gate length L_{G} of a MOSFET device to reduce R_{H}. However, doing so increases the parasitic capacitances C_{GS} and C_{GD}, thus degrading RF performance.

The present invention decreases R_{G} by a novel combination of gate structure and multiple gate conductive layer materials in a T-shaped geometry that results in a reduction in R_{H} while also reducing the gate length L_{G} of a MOSFET device below the lithographic capabilities of a fabrication process.

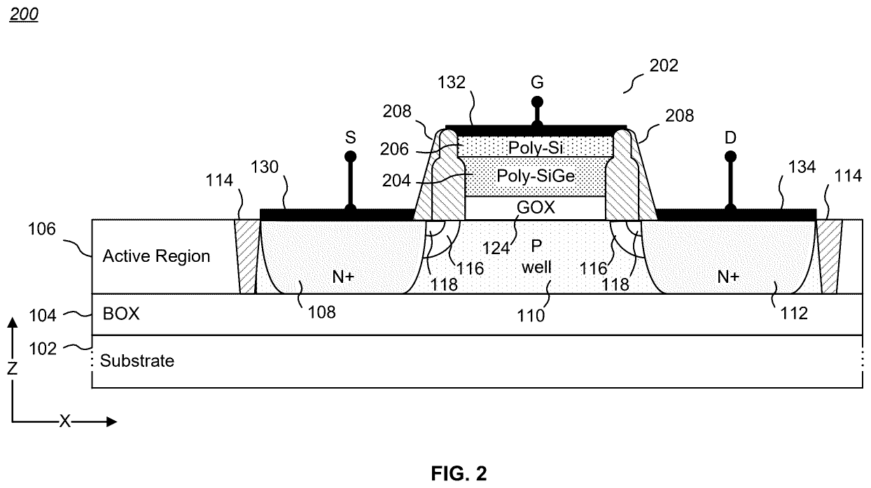

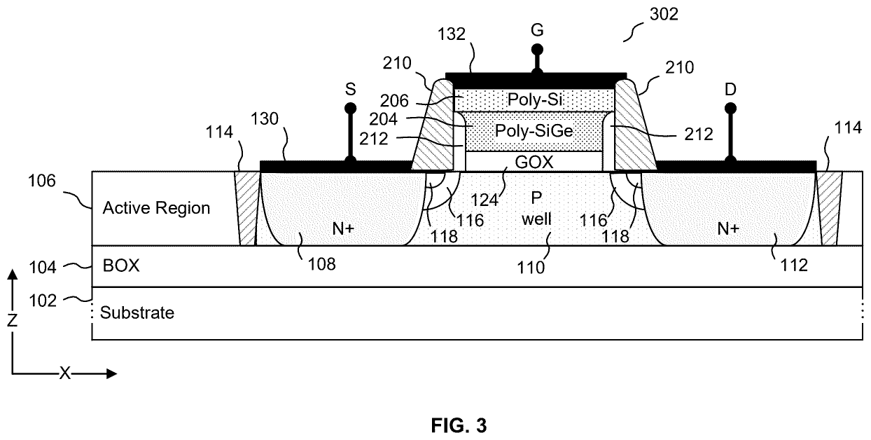

FIG. 2 is a stylized cross-sectional view of an SOI IC structure for a first example T-gate NFET 200 in accordance with the present invention. FIG. 3 is a stylized cross-sectional view of an SOI IC structure for a second example T-gate NFET 300 in accordance with the present invention.

Similar in some aspects to the NFETs 100 and 150 of FIGS. 1A and 1B, respectively, both the T-gate NFET 200 of FIG. 2 and the T-gate NFET 300 of FIG. 3 differ in important ways with respect to the gate structure.

In the example illustrated in FIGS. 2 and 3, the gate structure 202 of the T-gate NFET 200 and the gate structure 302 of the T-gate NFET 300 include a first conductive layer 204 of a first semiconductor material in contact with an insulating gate oxide (GOX) layer 124. A second conductive layer 206 of a second semiconductor material is formed in contact with the first conductive layer 204. A conductive gate contact 132, which may be a salicide (e.g., NiSi), is formed in contact with the second conductive layer 206.

The gate structure 202 of the T-gate NFET 200 is surrounded by conformal insulating side-spacers 208 on opposing sides of the gate structure 202, formed as detailed below. The gate structure 302 of the T-gate NFET 300 is surrounded by non-conformal insulating side-spacers 210 on opposing sides of the gate structure 302, formed as detailed below. The non-conformal insulating side-spacers 210 are formed such that air-gaps 212 separate some or all of at least the first conductive layer 204 from the non-conformal insulating side-spacers 210. The air-gaps 212 reduce parasitic gate-to-source capacitance C_{GS} and gate-to-drain capacitance C_{GD} with concomitant improved performance at high radio frequencies (RF), particularly at or above about 10 GHz.

For both the T-gate NFET 200 and the T-gate NFET 300, the first conductive layer 204 preferably comprises heterogeneous or homogenous poly-SiGe alloys (including Ge-doped Si, graded Ge and Si mixtures, or the like). For ease of manufacturing, it may be beneficial to use a homogenous SiGe alloy. The second conductive layer 206 preferably comprises polysilicon (poly-Si). The geometry of the gate structures 202, 302 forms a T-gate, with the first conductive layer 204 having a shorter length (source-to-drain in the X-dimension) than either the second conductive layer 206 or (in particular) the conductive gate contact 132.

The T-shape of the gate structures 202, 302 allows for a larger extent of the conductive gate contact 132 and second conductive layer 206 relative to gate length L_{G}, thus reducing R_{H} and accordingly reducing R_{G}, as desired. The presence of the poly-SiGe provides at least three significant benefits: (1) ease of manufacturing the T-shape of the gate structure 202, 302 due to the ability to preferentially etch (in multiple ways) poly-SiGe relative to polysilicon; (2) a lower sheet resistance than poly-Si, thus lowering the resistance R_{H} across the width of the gate in parallel with the conductive gate contact 132, and accordingly reducing R_{G}, as desired; and (3) greater flexibility in modulating the work function of the gate poly-SiGe via doping concentration to optimize the channel region for higher transconductance Gm values.

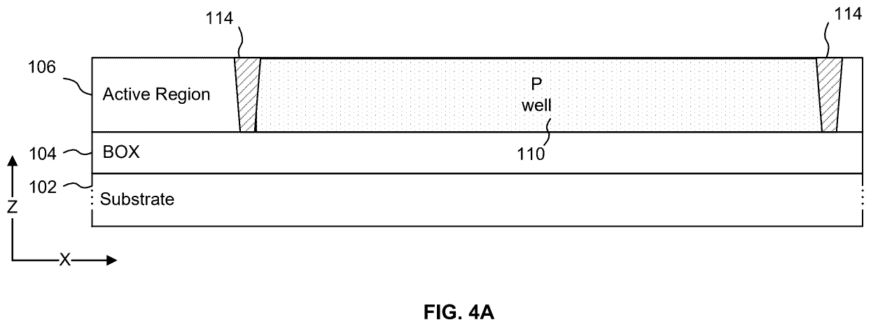

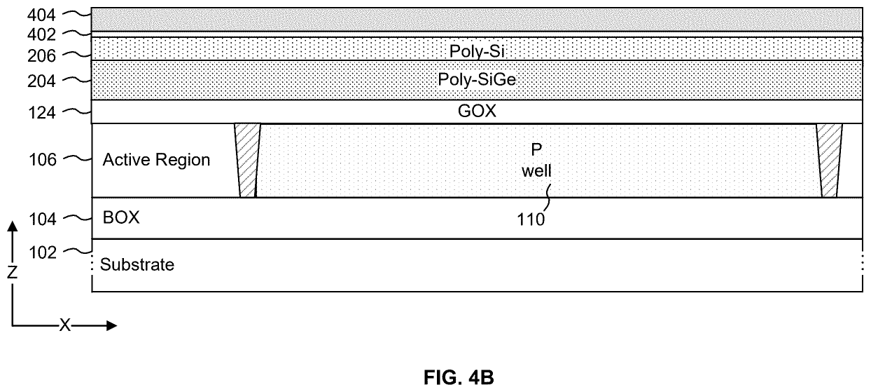

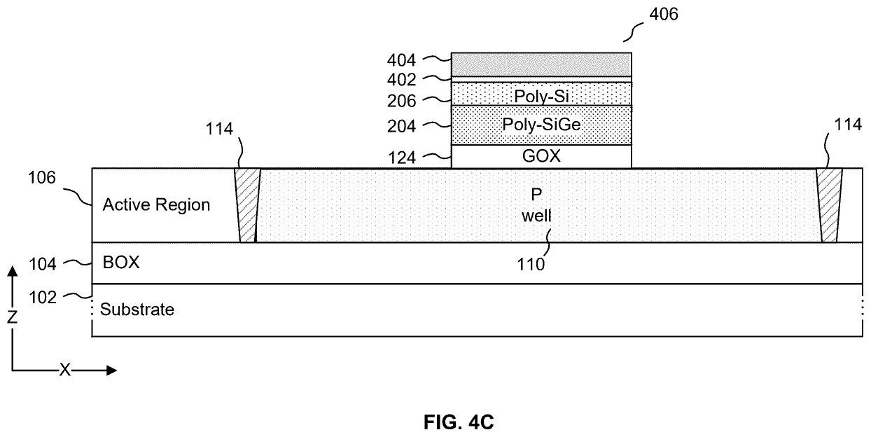

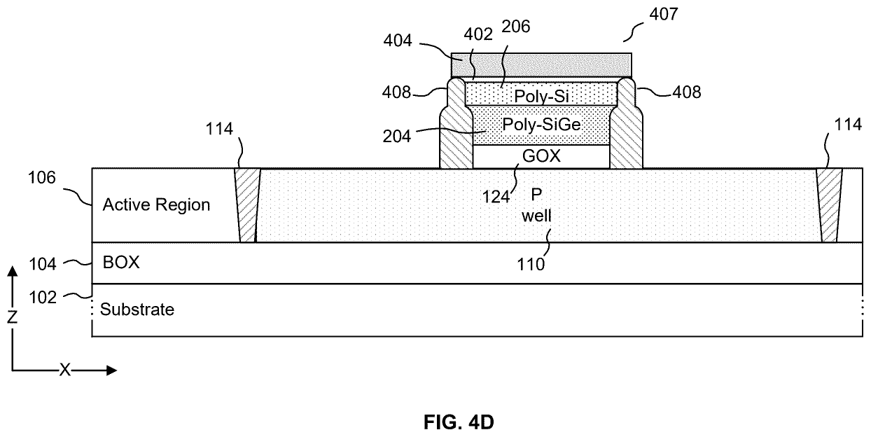

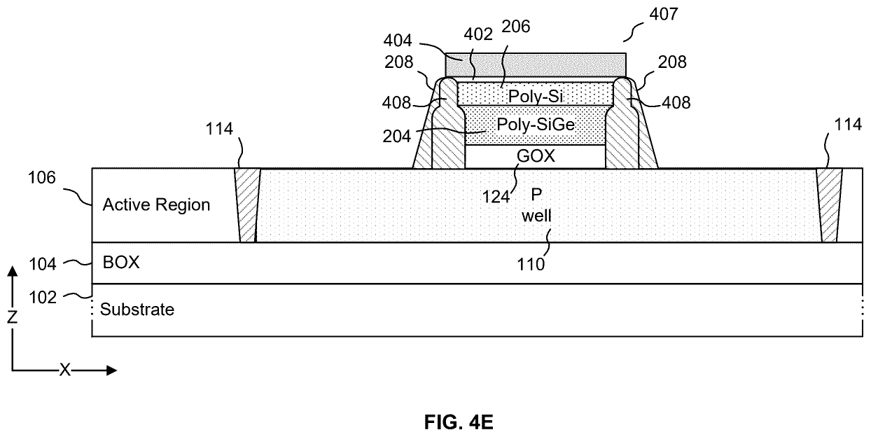

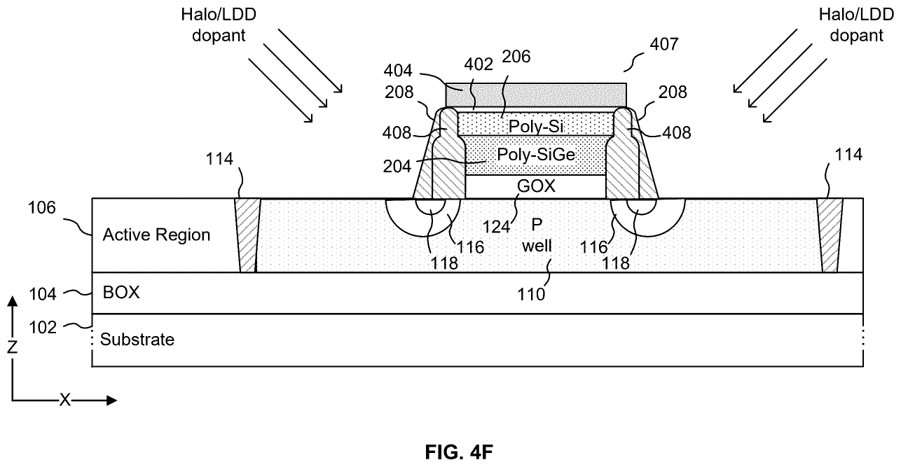

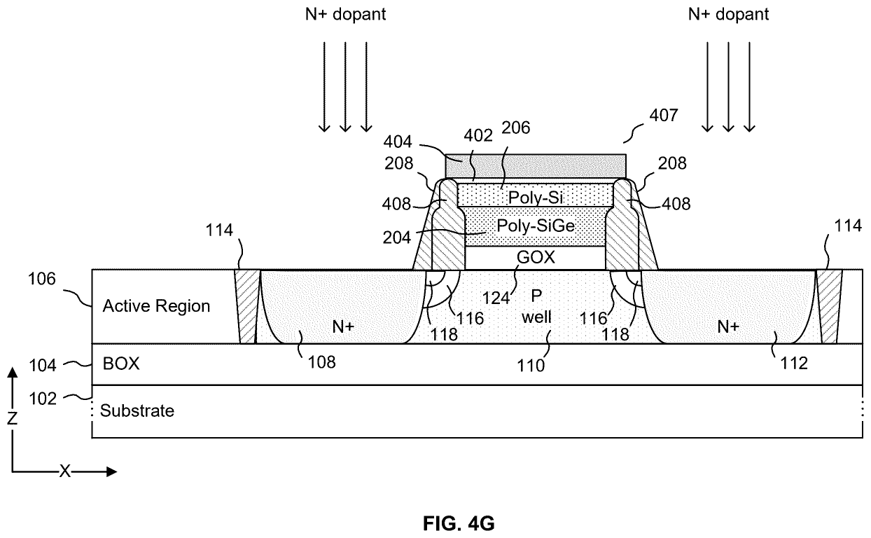

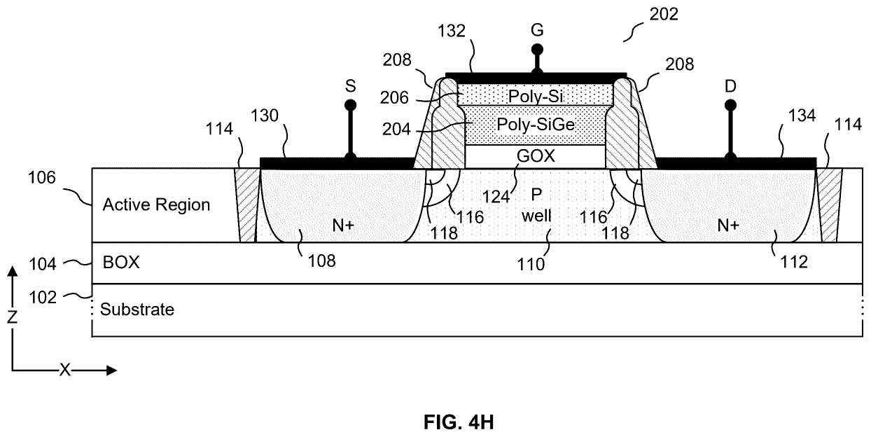

A number of different processes may be used to fabricate the novel T-gate NFET devices described in this disclosure. For example, FIGS. 4A-4H are cross-sectional stylized views of example fabrication stages for one method of fabricating the T-gate NFET 200 structure shown in FIG. 2.

FIG. 4A shows a portion of a semiconductor active layer 106 formed on a BOX layer 104, which is in turn formed on top of a substrate 102. In some embodiments, the active layer 106 may be formed directly on top of a bulk Si substrate 106, thus omitting the BOX layer 104, so long as some form of isolation is provided (and possibly a buried P+ layer). If needed, the active layer 106 may be thinned to a suitable thickness, such as by chemical-mechanical polishing (CMP). For example, commercially available SOI wafers may have an active layer thickness of about 750 Å. It may be useful for some applications, particularly for RF ICs, to thin the active layer 106, for example, to about 500 Å. Additionally, isolation structures 114 (e.g., STI's) have been formed. The active layer 106 may be masked and implanted to form a P-type body region or well 110.

FIG. 4B shows that a sequence of layers has been formed on the active layer 106: first a GOX layer 124 in contact with the active layer 106, next a poly-SiGe layer 204, next a polysilicon layer 206, next an oxide (e.g., SiO₂) layer 402, and then a mask layer 404. The poly-SiGe layer 204 and polysilicon layer 206 may each be, for example, about 500 Å in depth (Z-dimension). The mask layer 404 may be, for example, a hard mask of SiN. The various layers may be formed by any convenient means or combination of means, including thermal oxidation, epitaxial growth, and chemical vapor deposition (CVD).

The poly-SiGe layer 204 in particular may be formed in a variety of ways to achieve an SiGe alloy. For example, Ge and Si may be concurrently deposited in desired ratios (e.g., SiₓGe_{y}) by CVD or similar technologies to form an SiGe alloy. As another alternative, Si may be deposited initially and then implanted or diffused with Ge to form an SiGe alloy.

FIG. 4C shows a “block” initial gate structure 406 formed in contact with a surface of the active layer 106. The initial gate structure 406 may be formed by photolithography involving masking and then etching the GOX layer 124, the poly-SiGe layer 204, the polysilicon layer 206, the oxide layer 402, and the mask layer 404.

FIG. 4D shows that the sides of the GOX layer 124, the poly-SiGe layer 204, the polysilicon layer 206, and the oxide layer 402 have been subjected to a re-oxidation process to convert the side edges of Si or SiGe to an oxide. The differences in oxide conversion rates essentially transform the sides of those layers to form a T-shape out of the original layer materials and concurrently grow initial conformal side-spacers 408. The re-oxidation process may be performed, for example, at about 800° C. Notably, the poly-SiGe has a higher oxide growth rate than the polysilicon, resulting in the transformation of the essentially rectangular initial gate structure 406 of FIG. 4C into an intermediate T-shaped gate structure 407 (ignoring the geometry of the initial conformal side-spacers 408). Also of note is that the conversion to a T-shape reduces the gate length L_{G} of the initial gate structure 406 to be less than the length of the mask layer 404 (measured source-to-drain in the X-dimension). Accordingly, the gate length L_{G} may be scaled below the lithographic capabilities of the fabrication process.

FIG. 4E shows that the initial conformal side-spacers 408 have been extended by deposition of SiO₂ or SiN to form the final conformal insulating side-spacers 208. Deposition may be, for example, by CVD in conjunction with anisotropic etching and/or suitable masking.

FIG. 4F shows that halo regions 116 and/or LDD regions 118 may be formed by implantation of a suitable dopant in conjunction with suitable masking. The values of implantation angles (measured from vertical) typically differ for halo region 116 implants versus LDD region 118 implants—for example, a tilt angle θ may be about 30° for halo region 116 implants, and about 10° for LDD region 118 implants.

FIG. 4G shows that the source 108 and the drain 112 are formed by implantation of an N+ dopant in conjunction with suitable masking.

FIG. 4H shows that the mask layer 404 and oxide layer 402 have been removed. In addition, a conductive source contact 130, a conductive gate contact 132, and a conductive drain contact 134, which may be self-aligned silicides (also known as “salicides”), are respectively formed in contact with the source 108, the polysilicon layer 206, and the drain 112. The intermediate T-shaped gate structure 407 is thus completed and corresponds to the final gate structure 202 of FIG. 2.

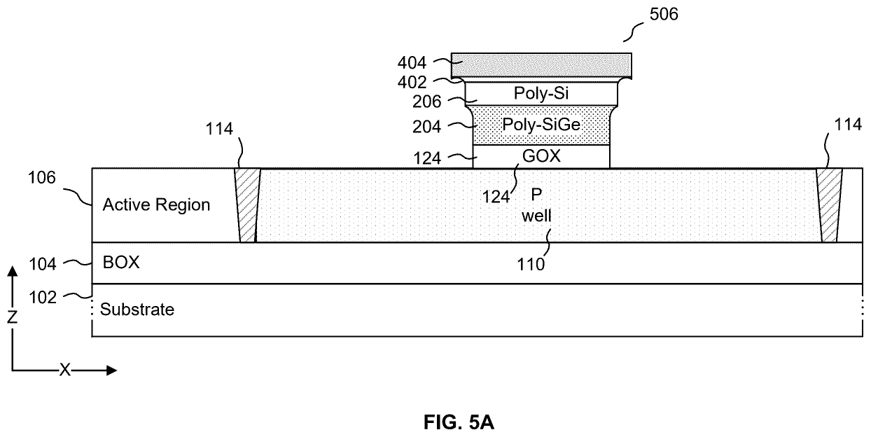

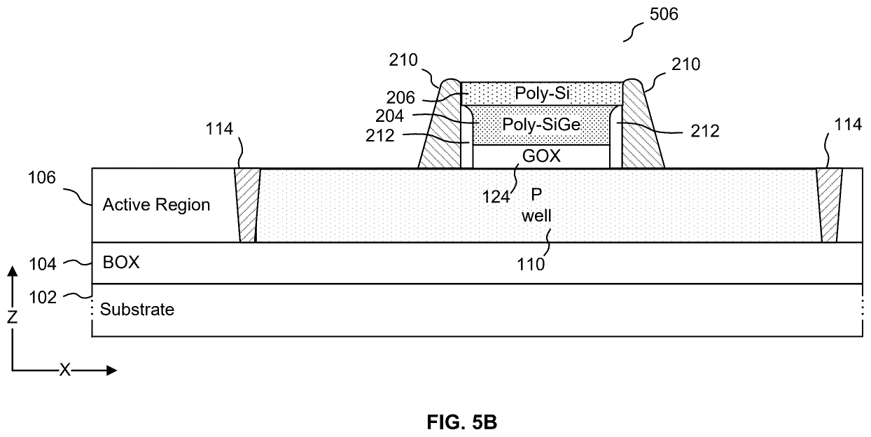

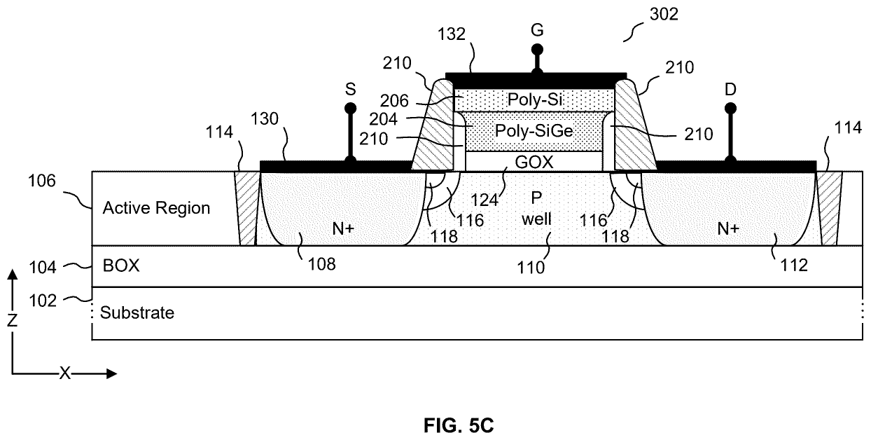

FIGS. 5A-5C are cross-sectional stylized views of example fabrication stages for one method of fabricating the T-gate NFET 300 structure shown in FIG. 3.

FIG. 5A shows a stage that is preceded by the stages shown in FIGS. 5A-5C. At the stage illustrated in FIG. 5A, at least the poly-SiGe layer 204 and the polysilicon layer 206 are isotropically etched by a liquid or gaseous etchant to form voids that are to become the air-gaps 212. Notably, the poly-SiGe has a higher etch rate than the polysilicon, resulting in the transformation of the essentially rectangular initial gate structure 406 into an intermediate T-shaped gate structure 506. The etchant may be buffered HF or, in some cases, water—SiGe is a water-soluble metal if the concentration of Ge is suitably high (e.g., about 30-50% of the SiGe alloy).

FIG. 5B shows that non-conformal insulating side-spacers 210 are formed, such as by CVD in conjunction with suitable masking, and that the mask layer 404 and oxide layer 402 have been removed. The voids created in the stage shown in FIG. 5A are now air-gaps 212.

FIG. 5C shows the result after the process continues as shown in FIGS. 4F-4H. The intermediate T-shaped gate structure 506 is completed and corresponds to the final gate structure 302 of FIG. 3.

It should be appreciated that fabrication of the novel T-gate NFET devices in accordance with the present invention, as well as variants, may be accomplished using alternative additive and/or subtractive process steps. Note that not all steps that may be performed during the manufacture of a novel FET device as part of an IC are shown in the aforementioned figures. Such steps may vary between IC foundries and may include (but are not limited to) substrate thinning, planarization, special implantations, annealing, formation of ohmic contacts, and formation of additional temporary or permanent structures (e.g., drift regions, substrate contacts, passivation layers, salicide blocks, etc. After formation of a basic MOSFET structure, back-end-of-line (BEOL) processes may be applied, such as fabrication of electrical contacts (pads), vias, insulating layers (dielectrics), metallization layers, and bonding sites for die-to-package connections.

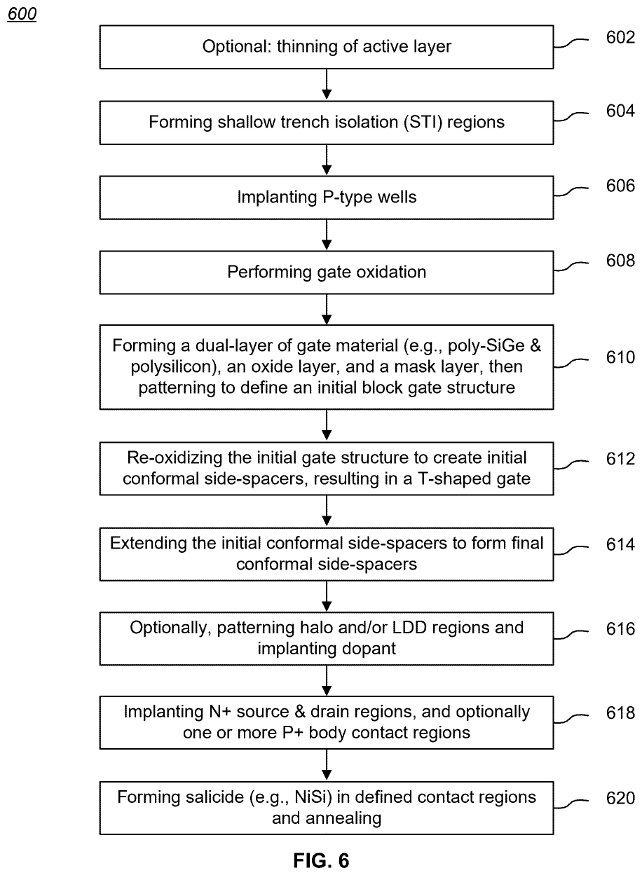

FIG. 6 is a process flowchart 600 showing another representation of an example fabrication process for the T-gate NFET 200 of FIG. 2. The illustrated process is suitable for some contemporary IC front-end-of-line (FEOL) foundries. Note that some conventional steps, such as planarization, passivation, details of masking and etching, and superstructure formation have been omitted as known to those of ordinary skill in the art. The illustrated process includes:

If needed, thinning the semiconductor active layer (e.g., Si, Ge, SiGe, SiC, or the like) formed on a substrate to a suitable thickness (Step 602).

Forming shallow trench isolation (STI) regions (Step 604).

Forming a P-type well (Step 606).

Performing gate oxidation (Step 608).

Forming a dual-layer of gate material (e.g., poly-SiGe followed by polysilicon), an oxide layer, and a mask layer (e.g., SiN), then patterning (e.g., masking and etching) to define an initial block gate structure (Step 610).

Re-oxidizing the initial gate structure to create initial conformal side-spacers, resulting in a T-shaped gate (Step 612).

Extending the initial conformal side-spacers to form final conformal side-spacers (Step 614).

Optionally, patterning source-side halo and/or LDD regions and implanting dopant (Step 616).

Implanting an N+ source region, an N+ drain region, and optionally one or more P+ body contact regions (Step 618). The gate material may also be implanted at the same time.

Forming salicide (e.g., NiSi) in defined contact regions (such as by reacting a metal with the Si) and annealing (Step 620).

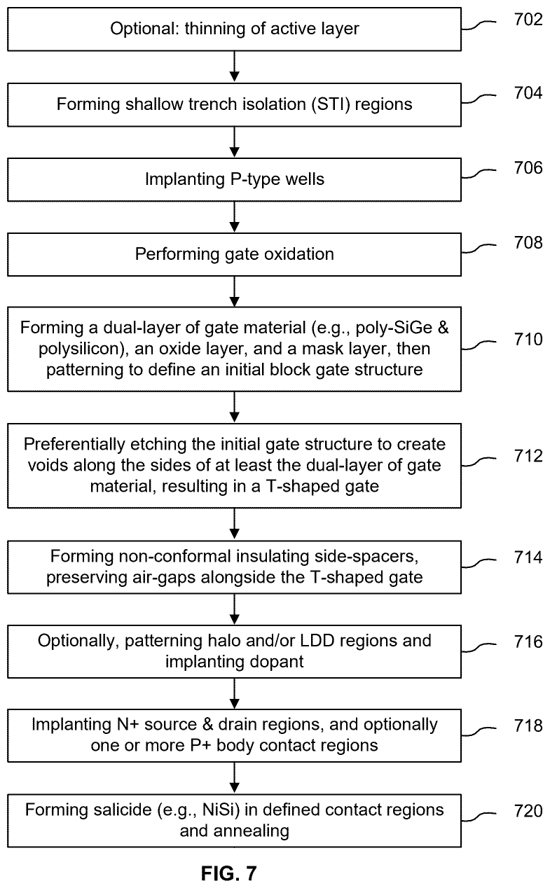

FIG. 7 is a process flowchart 700 showing another representation of an example fabrication process for the T-gate NFET 300 of FIG. 3. The illustrated process is suitable for some contemporary IC front-end-of-line (FEOL) foundries. Again, note that some conventional steps, such as planarization, passivation, details of masking and etching, and superstructure formation have been omitted as known to those of ordinary skill in the art. The illustrated process includes:

If needed, thinning the semiconductor active layer (e.g., Si, Ge, SiGe, SiC, or the like) formed on a substrate to a suitable thickness (Step 702).

Forming shallow trench isolation (STI) regions (Step 704).

Forming a P-type well (Step 706).

Performing gate oxidation (Step 708).

Forming a dual-layer of gate material (e.g., poly-SiGe followed by polysilicon), an oxide layer, and a mask layer (e.g., SiN), then patterning (e.g., masking and etching) to define an initial block gate structure (Step 710).

Preferentially etching the initial gate structure to create voids along the sides of at least the dual-layer of gate material, resulting in a T-shaped gate (Step 712).

Forming non-conformal insulating side-spacers, preserving air-gaps alongside the T-shaped gate (Step 714).

Optionally, patterning source-side halo and/or LDD regions and implanting dopant (Step 716).

Implanting an N+ source region, an N+ drain region, and optionally one or more P+ body contact regions (Step 718). The gate material may also be implanted at the same time.

Forming salicide (e.g., NiSi) in defined contact regions (such as by reacting a metal with the Si) and annealing (Step 720).

As should be appreciated, other “recipes” that include additive and/or subtractive process steps may be used to fabricate essentially the same novel T-gate NFETs 200, 300 and variant structures. Further, the fabrications steps may be performed in any feasible order.

It is common to include a Body-Tied-to-Source (BTS) structure for MOSFETs, and a BTS configuration may be used with the inventive T-gate NFET devices. Some embodiments of such devices may include a centrally-located BTS structure comprising a P+ body contact region fabricated in a conventional manner to electrically connect to the body (e.g., the P-well 110 in FIGS. 2 and 3) of the device and provide a fourth terminal for the device. Some embodiments of such devices may include two end-positioned BTS structures comprising P+ body contact regions and associated contacts parallel to the X-dimension edges of the device, which reduces current leakage by increasing the V_{TH} at those edges. Having more than one BTS structure provides more efficient charge carrier collection compared to a single central BTS structure. Some embodiments of such devices may include two end-positioned BTS structures and one or more BTS structures positioned at intermediate locations between the end-positioned BTS structures.

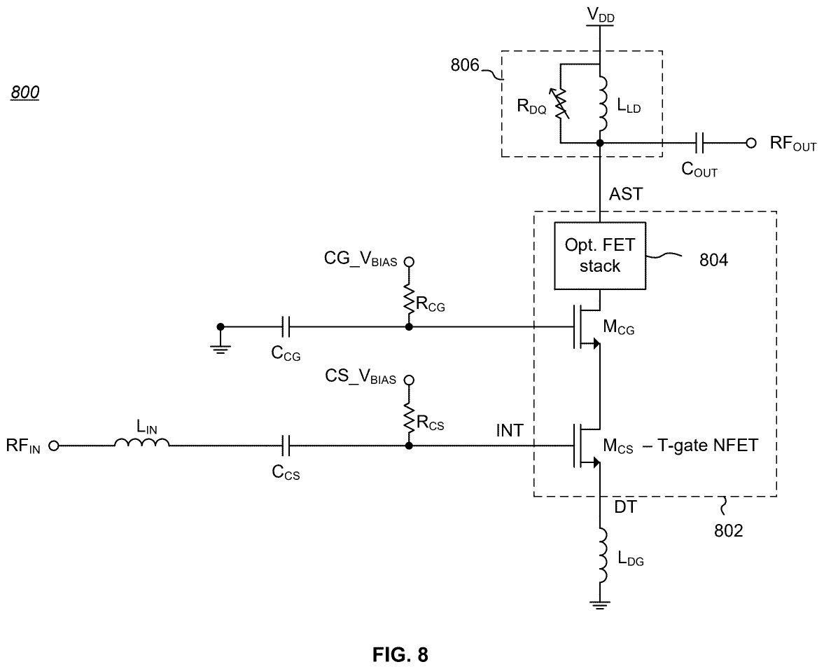

The novel T-gate NFETs 200, 300 may be beneficially used to improve the performance of a wide range of RF circuits, including LNA circuits. For example, FIG. 8 is a simplified schematic diagram of an LNA circuit 800. In the illustrated example, the LNA circuit 800 includes an amplifier core 802 comprising a stack of two series-connected FETs: a common-source NFET M_{CS} and a common-gate NFET device M_{CG} coupled in a cascode arrangement. At least the common-source NFET device M_{CS} should be a T-gate NFET as described in this disclosure, in order to improve the noise figure NFmin of the circuit. Optionally, the common-gate NFET device M_{CG} may be a T-gate NFET as described in this disclosure. An optional FET device stack 804 may be coupled to the drain of the common-gate NFET device M_{CG} to handle higher voltages; one or more of the component FETs in the FET device stack 804 may be a multiple gate conductive layer T-gate NFET as described in this disclosure.

An RF input signal applied to an RF input terminal RF_{IN} is coupled through an impedance matching inductor L_{IN} and a DC blocking capacitor Ccs to the control gate of the common-source NFET device M_{CS} (which may be regarded as an input port INT of the amplification core 802). The control gate of the common-gate NFET device M_{CG} is coupled through a capacitor CCG to a reference potential (e.g., circuit ground).

The source of the common-source NFET device M_{CS} may be regarded as a degeneration port DT of the amplification core 802. A degeneration inductor L_{DG} is shown coupled between the degeneration port DT of the amplification core 802 and a reference potential, such as circuit ground.

The source of the common-gate NFET device M_{CG} is connected to the drain of the common-source FET device M_{CS}. The drain of the common-gate NFET device M_{CG} provides an amplified RF output signal (directly or through the optional FET stack 804) at what may be regarded as an amplified-signal port AST of the amplification core 802.

A bias generator circuit (not shown) may be included to provide a suitable bias voltage CG_V_{BIAS} to the common-gate NFET device M_{CG} through a resistor R_{CG} and a suitable bias voltage CS_V_{BIAS} to the common-source NFET device M_{CS} through a resistor R_{CS}.

In the illustrated example, the amplified-signal port AST is coupled to a voltage source terminal V_{DD} through a load module 806. In the illustrated example, the load module 806 includes a load inductor L_{LD} coupled in parallel with a de-queuing resistor R_{DQ}. The amplified-signal port AST is also coupled to an RF output terminal RF_{OUT} through a DC-blocking output capacitor C_{OUT}. The RF output terminal RF_{OUT} would typically be coupled to a 50-ohm load for many modern RF circuits.

The Noise Factor (NF) of an RF receiver is set by an LNA front-end, and the common-source device M_{CS} fundamentally sets the NF of the LNA. Accordingly, utilizing a multiple gate conductive layer T-gate NFET as described in this disclosure as the common-source device M_{CS} in an LNA results in an improved NF and thus in improved performance, particularly at high radio frequencies.

As should be appreciated, a wide range of variant circuits can be designed based on the simplified LNA circuit 800 of FIG. 8. A number of variant LNAs may benefit from the use of the present invention. For example, additional control and configuration switches may be included, and the LNA circuit 800 may include more than one amplifier core 802. Additional circuitry may include (1) an output clamp coupled between the output terminal RF_{OUT} and the reference potential to clamp transient signals, (2) a filter capacitor coupled between the voltage source terminal V_{DD} and the reference potential to filter noise that may be present at that node, and (3) a clamp diode coupled between the voltage source terminal V_{DD} and the amplified-signal port AST to reduce the voltage swing at the LNA output, which may benefit parameter specifications (e.g., output saturation power) that are required in many applications. In some variants, the bias voltages may be variable, the degeneration inductor L_{DG} may be variable and/or bypassable, the load module 806 may include additional and/or more complex (e.g., variable and/or bypassable) LRC components, and feedback circuitry may be coupled between the amplified-signal port AST and the input port INT. Configuration switches may be used to selectively connect or disconnect various circuit elements, for example, to accommodate different gain modes of operation.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

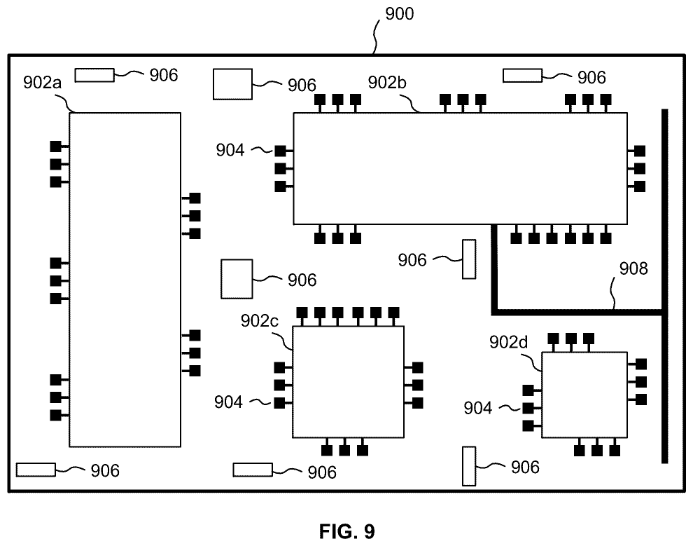

As one example of further integration of embodiments of the present invention with other components, FIG. 9 is a top plan view of a substrate 900 that may be, for example, a printed circuit board or chip module substrate (e.g., a thin-film tile). In the illustrated example, the substrate 900 includes multiple ICs 902a-902d having terminal pads 904 which would be interconnected by conductive vias and/or traces on and/or within the substrate 900 or on the opposite (back) surface of the substrate 900 (to avoid clutter, the surface conductive traces are not shown and not all terminal pads are labelled). The ICs 902a-902d may embody, for example, signal switches, active and/or passive filters, amplifiers (including one or more LNAs), and other circuitry. For example, IC 902b may incorporate one or more instances of a circuit that includes one or more T-gate NFETs fabricated in accordance with the teachings of this disclosure.

The substrate 900 may also include one or more passive devices 906 embedded in, formed on, and/or affixed to the substrate 900. While shown as generic rectangles, the passive devices 906 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 900 to other passive devices 906 and/or the individual ICs 902a-902d. The front or back surface of the substrate 900 may be used as a location for the formation of other structures.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

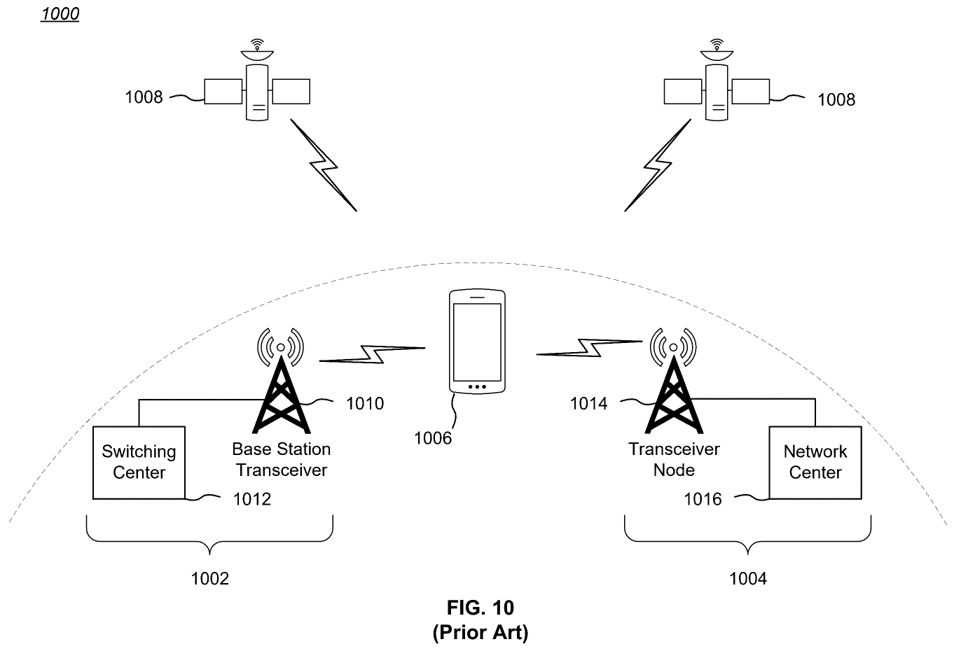

As an example of wireless RF system usage, FIG. 10 illustrates a prior art wireless communication environment 1000 comprising different wireless communication systems 1002 and 1004, and which may include one or more mobile wireless devices 1006. A wireless device 1006 may be a cellular phone, a wireless-enabled computer or tablet, or some other wireless communication unit or device. A wireless device 1006 may also be referred to as a mobile station, user equipment, an access terminal, or some other terminology known in the telecommunications industry.

A wireless device 1006 may be capable of communicating with multiple wireless communication systems 1002, 1004 using one or more of telecommunication protocols such as the protocols noted above. A wireless device 1006 also may be capable of communicating with one or more satellites 1008, such as navigation satellites (e.g., GPS) and/or telecommunication satellites. The wireless device 1006 may be equipped with multiple antennas, externally and/or internally, for operation on different frequencies and/or to provide diversity against deleterious path effects such as fading and multi-path interference.

The wireless communication system 1002 may be, for example, a CDMA-based system that includes one or more base station transceivers (BSTs) 1010 and at least one switching center (SC) 1012. Each BST 1010 provides over-the-air RF communication for wireless devices 1006 within its coverage area. The SC 1012 couples to one or more BSTs 1010 in the wireless system 1002 and provides coordination and control for those BSTs 1010.

The wireless communication system 1004 may be, for example, a TDMA-based system that includes one or more transceiver nodes 1014 and a network center (NC) 1016. Each transceiver node 1014 provides over-the-air RF communication for wireless devices 1006 within its coverage area. The NC 1016 couples to one or more transceiver nodes 1014 in the wireless system 1004 and provides coordination and control for those transceiver nodes 1014.

In general, each BST 1010 and transceiver node 1014 is a fixed station that provides communication coverage for wireless devices 1006, and may also be referred to as base stations or some other terminology known in the telecommunications industry. The SC 1012 and the NC 1016 are network entities that provide coordination and control for the base stations and may also be referred to by other terminologies known in the telecommunications industry.

Of note, every node in FIG. 10 includes a radio receiver and therefore will benefit from this present invention by improving the NF of each node.

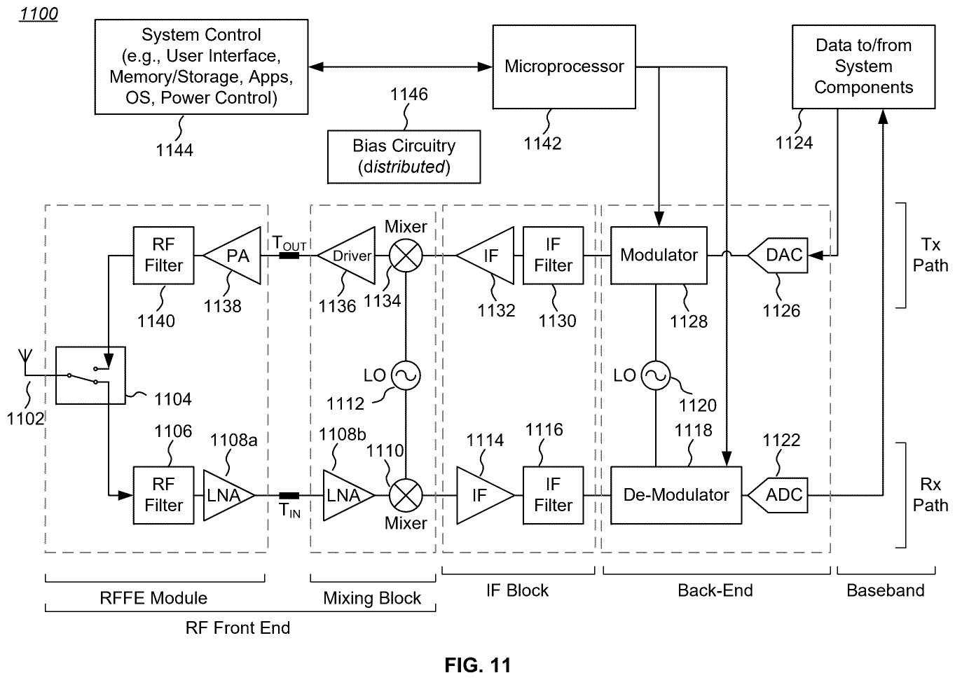

An important aspect of any wireless system, including the systems shown in FIG. 10, is in the details of how the component elements of the system perform. FIG. 11 is a block diagram of a transceiver 1100 that might be used in a wireless device, such as a cellular telephone, and which may beneficially incorporate an embodiment of the present invention for improved performance. As illustrated, the transceiver 1100 includes a mix of RF analog circuitry for directly conveying and/or transforming signals on an RF signal path, non-RF analog circuitry for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines T_{IN} and T_{OUT} (e.g., microstrips, co-planar waveguides, or an equivalent structure or circuit), either or both of which may have, for example, a 50Ω impedance.

The receiver path Rx receives over-the-air RF signals through at least one antenna 1102 and a switching unit 1104, which may be implemented with active switching devices (e.g., field effect transistors or FETs) and/or with passive devices that implement frequency-domain multiplexing, such as a diplexer or duplexer. An RF filter 1106 passes desired received RF signals to at least one low noise amplifier (LNA) 1108a, the output of which is coupled from the RFFE Module to at least one LNA 1108b in the Mixing Block (through transmission line T_{IN} in this example). The LNA(s) 1108b may provide buffering, input matching, and reverse isolation. In some embodiments, the LNA(s) 1108a and 1108b may be a single LNA. The LNAs may, for example, be similar to the LNA circuit 800 shown in FIG. 8.

The output of the LNA(s) 1108b is combined in a corresponding mixer 1110 with the output of a first local oscillator 1112 to produce an IF signal. The IF signal may be amplified by an IF amplifier 1114 and subjected to an IF filter 1116 before being applied to a demodulator 1118, which may be coupled to a second local oscillator 1120. The demodulated output of the demodulator 1118 is transformed to a digital signal by an analog-to-digital converter 1122 and provided to one or more system components 1124 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system components 1124 is transformed to an analog signal by a digital-to-analog converter 1126, the output of which is applied to a modulator 1128, which also may be coupled to the second local oscillator 1120. The modulated output of the modulator 1128 may be subjected to an IF filter 1130 before being amplified by an IF amplifier 1132. The output of the IF amplifier 1132 is then combined in a mixer 1134 with the output of the first local oscillator 1112 to produce an RF signal. The RF signal may be amplified by a driver 1136, the output of which is coupled to a power amplifier (PA) 1138 (through transmission line Tour in this example). The amplified RF signal may be coupled to an RF filter 1140, the output of which is coupled to at least one antenna 1102 through the switching unit 1104.

The operation of the transceiver 1100 is controlled by a microprocessor 1142 in known fashion, which interacts with system control components 1144 (e.g., user interfaces, memory/storage devices, application programs, operating system software, power control, etc.). In addition, the transceiver 1100 will generally include other circuitry, such as bias circuitry 1146 (which may be distributed throughout the transceiver 1100 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components of the transceiver 1100 may be positioned in a different order (e.g., filters) or omitted. Other components can be (and often are) added, such as (by way of example only) additional filters, impedance matching networks, variable phase shifters/attenuators, power dividers, etc.

As should be appreciated, one or more of the components shown in FIG. 11 may include multiple NFET devices, and one or more of such NFET devices may be a T-gate NFET of the type described in this disclosure.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, MESFET, FinFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A T-shaped gate for a field-effect transistor (FET), including:
(a) a gate oxide layer in contact with an active layer of the FET;
(b) a first conductive layer in contact with the gate oxide layer;
(c) a second conductive layer in contact with the first conductive layer; and
(d) a conductive gate contact in contact with the second conductive layer;
wherein at least the first conductive layer has a shorter length than the conductive gate contact and a higher etch rate than the second conductive layer.

2. The T-shaped gate of claim 1, wherein the second conductive layer has a shorter length than the conductive gate contact.

3. The T-shaped gate of claim 1, wherein the first conductive layer comprises a poly-SiGe alloy.

4. The T-shaped gate of claim 1, wherein the first conductive layer comprises polysilicon.

5. The T-shaped gate of claim 1, wherein the conductive gate contact includes a silicide.

6. The T-shaped gate of claim 1, further including conformal insulating side-spacers on opposing sides of the T-shaped gate.

7. The T-shaped gate of claim 1, further including non-conformal insulating side-spacers on opposing sides of the T-shaped gate, formed such that air-gaps separate some or all of at least the first conductive layer from the non-conformal insulating side-spacers.

8. A T-shaped gate for a field-effect transistor (FET), including:
(a) a gate oxide layer in contact with an active layer of the FET;
(b) a poly-SiGe layer in contact with the gate oxide layer;
(c) a polysilicon layer in contact with the poly-SiGe layer; and
(d) a conductive gate contact in contact with the polysilicon layer;
wherein at least the poly-SiGe layer has a shorter length than the conductive gate contact.

9. The T-shaped gate of claim 8, wherein the polysilicon layer has a shorter length than the conductive gate contact.

10. The T-shaped gate of claim 8, wherein the conductive gate contact includes a silicide.

11. The T-shaped gate of claim 8, further including conformal insulating side-spacers on opposing sides of the T-shaped gate.

12. The T-shaped gate of claim 8, further including non-conformal insulating side-spacers on opposing sides of the T-shaped gate, formed such that air-gaps separate some or all of at least the first conductive layer from the non-conformal insulating side-spacers.

13. A metal-oxide-semiconductor field-effect transistor (MOSFET) having an active layer and including:
(a) a source region formed within the active layer of the MOSFET;
(b) a drain region formed within the active layer of the MOSFET;
(c) a body region within the active layer of the MOSFET between the source region and the drain region; and
(d) a T-shaped gate structure overlying the body region, the gate structure having a source region side and a drain region side and positioned to influence current flow through the body region, the T-shaped gate structure including:
(1) a gate oxide layer in contact with an active layer of the FET;
(2) a first conductive layer in contact with the gate oxide layer;
(3) a second conductive layer in contact with the first conductive layer; and
(4) a conductive gate contact in contact with the second conductive layer;
wherein at least the first conductive layer has a shorter length than the conductive gate contact and a higher etch rate than the second conductive layer.

14. The MOSFET of claim 13, further including at least one of a halo region or lightly-doped drain region located in the body region between the source region and the body region and/or between the drain region and the body region.

15. The MOSFET of claim 13, wherein the second conductive layer has a shorter length than the conductive gate contact.

16. The MOSFET of claim 13, wherein the first conductive layer comprises a poly-SiGe alloy.

17. The MOSFET of claim 13, wherein the first conductive layer comprises polysilicon.

18. The MOSFET of claim 13, wherein the conductive gate contact includes a silicide.

19. The MOSFET of claim 13, further including conformal insulating side-spacers on opposing sides of the T-shaped gate structure.

20. The MOSFET of claim 13, further including non-conformal insulating side-spacers on opposing sides of the T-shaped gate structure, formed such that air-gaps separate some or all of at least the first conductive layer from the non-conformal insulating side-spacers.

21.-35. (canceled)
